(19) United States
(12) Patent Application Publication
(10) Pub. No.: US 2026/0108893 A1
(43) Pub. Date: Apr. 23, 2026

(54) MASK ASSEMBLY AND METHOD OF MANUFACTURING THE SAME

(71) Applicant: Samsung Display Co., Ltd., Yongin-si (KR)

(72) Inventors: JUNGWOON JUNG, Yongin-si (KR); KI YOUNG YEON, Yongin-si (KR); DONGYOUN YOO, Yongin-si (KR); JAE-BUM HAN, Yongin-si (KR)

(21) Appl. No.: 19/297,610

(22) Filed: Aug. 12, 2025

(30) Foreign Application Priority Data
Oct. 21, 2024 (KR) 10-2024-0143682

(51) Int. Cl. B05B 1/14; C23C 16/34; C23C 16/40; C23C 16/56; H10K 71/16

(52) U.S. Cl. CPC B05B 1/1421; C23C 16/345; C23C 16/401; C23C 16/403; C23C 16/56; H10K 71/166

(57) ABSTRACT

A manufacturing method of a mask assembly includes providing a wafer, forming a first inorganic layer on the wafer, forming a second inorganic layer on the first inorganic layer, etching the wafer to form a cell opening, forming a photosensitive layer on a rear surface of the first inorganic layer exposed through the cell opening, etching the photosensitive layer to form photo openings, isotropically etching the first inorganic layer to form first openings overlapping the photo openings, and anisotropically etching the second inorganic layer to form second openings overlapping the first openings.

This application claims priority to Korean Patent Application No. 10-2024-0143682, filed on Oct. 21, 2024, and all the benefits accruing therefrom under 35 U.S. C. § 119, the content of which in its entirety is herein incorporated by reference.

### BACKGROUND

### 1. Field

The present disclosure relates to a mask assembly and a method of manufacturing a mask assembly. More particularly, the present disclosure relates to a method of manufacturing a mask assembly used in a deposition process.

### 2. Description of Related Art

A display device typically includes pixels, and each pixel may include a driving element such as a transistor and a display element such as an organic light emitting diode.

The display element may be formed by stacking an electrode and a light emitting pattern on a substrate.

A process of using a mask assembly, through which openings are defined, may be performed to form the light emitting pattern. The light emitting pattern is formed corresponding to an area, which is exposed through the opening of the mask assembly. The light emitting pattern is formed on a target substrate in accordance with the shape and location of the opening of the mask assembly.

### SUMMARY

The present disclosure provides a method of manufacturing a mask assembly that allows a side surface of mask openings defining openings of the mask assembly to have a selected angle.

The present disclosure provides a mask assembly capable of preventing or reducing the occurrence of a shadow area in which a deposition pattern is formed unevenly in thickness in a process of depositing a deposition material on a target substrate.

Embodiments of the invention provide a method of manufacturing a mask assembly. In such embodiments, the method includes providing a wafer, forming a first inorganic layer on the wafer, forming a second inorganic layer on the first inorganic layer, etching the wafer to form a cell opening, forming a photosensitive layer on a rear surface of the first inorganic layer exposed through the cell opening, etching the photosensitive layer to form photo openings, isotropically etching the first inorganic layer to form first openings overlapping the photo openings, and anisotropically etching the second inorganic layer to form second openings overlapping the first openings.

In an embodiment, the forming the first openings may include wet-etching the first inorganic layer along a direction from the rear surface of the first inorganic layer to an upper surface of the first inorganic layer.

In an embodiment, the forming the second openings may include dry-etching the second inorganic layer along a direction from a rear surface of the second inorganic layer to an upper surface of the second inorganic layer.

In an embodiment, the forming the first inorganic layer may include depositing one of silicon oxide (SiOx) and aluminum oxide (AlOx) on an upper surface of the wafer through a chemical vapor deposition (CVD) process.

In an embodiment, the forming the second inorganic layer may include depositing silicon nitride (SiNx) on the upper surface of the first inorganic layer through a chemical vapor deposition (CVD) process.

In an embodiment, the forming the first openings may include etching a portion of the rear surface of the first inorganic layer, which is exposed through the photo openings, in a direction from the rear surface of the first inorganic layer to the upper surface of the first inorganic layer.

In an embodiment, the forming the second openings may include etching a portion of the rear surface of the second inorganic layer, which is exposed through the first openings, in a direction from the rear surface of the second inorganic layer to the upper surface of the second inorganic layer.

In an embodiment, the method may further include removing the photosensitive layer.

In an embodiment, the removing the photosensitive layer may include wet-stripping the photosensitive layer.

In an embodiment, each of side surfaces the first inorganic layer, which defines the first openings, may have an under-cut shape when viewed in a cross-section after the forming the first openings and before the removing the photosensitive layer.

In an embodiment, the forming the cell opening may include wet-etching the wafer in a direction from a rear surface of the wafer to the upper surface of the wafer.

In an embodiment, the cell opening may have a width which decreases in a direction from the rear surface of the wafer to the upper surface of the wafer when viewed in the cross-section.

In an embodiment, the first inorganic layer may have a thickness greater than or equal to about 100 nanometers (nm) and less than or equal to about 2 micrometers (μm), and the second inorganic layer may have a thickness greater than or equal to about 5 nm and less than or equal to about 50 nm.

Embodiments of the invention provide a mask assembly including a wafer through which cell openings are defined, a first inorganic layer disposed on the wafer and provided with first openings completely penetrating through upper and rear surfaces of the first inorganic layer, and a second inorganic layer disposed on the first inorganic layer and provided with second openings defined through the second inorganic layer and overlapping the first openings. In such embodiments, each of the first openings has a width which decreases in a direction from the rear surface of the first inorganic layer to the upper surface of the first inorganic layer.

In an embodiment, the first inorganic layer may have a thickness greater than a thickness of the second inorganic layer.

In an embodiment, the first inorganic layer may have a thickness greater than or equal to about 100 nm and less than or equal to about 2μm.

In an embodiment, the second inorganic layer may have a thickness greater than or equal to about 5 nm and less than or equal to about 50 nm.

In an embodiment, each of the cell openings may overlap the first openings and the second openings when viewed in a plan view.

In an embodiment, the wafer may include silicon, the first inorganic layer may include one of silicon oxide (SiOx) and aluminum oxide (AlOx), and the second inorganic layer includes silicon nitride (SiNx).

In an embodiment, each of the cell openings may completely penetrate through the wafer in a thickness direction, and each of the cell openings may have a width that decreases in a direction from a rear surface of the wafer to an upper surface of the wafer when viewed in a cross-section.

In an embodiment, the second openings may be spaced apart from each other when viewed in the plan view.

In an embodiment, the first inorganic layer may have a single-layer structure, and the second inorganic layer has a multi-layer structure.

According to embodiments of the invention, the occurrence of a shadow area where the deposition material is deposited with a non-uniform thickness is reduced in the mask assembly manufactured through the manufacturing method of the mask assembly.

According to embodiments of the invention, the manufacturing method of the mask assembly is simplified, and the cost and time consumed in the manufacturing process are reduced.

According to embodiments of the invention, when a mask manufactured according to the manufacturing method of the mask assembly is used in a deposition process, the yield and reliability of the deposition process are improved. Furthermore, the resolution, brightness, and lifespan of a display device manufactured through the deposition process are also enhanced.

### BRIEF DESCRIPTION OF THE DRAWINGS

FIG. 1 is a perspective view illustrating an electronic device according to an embodiment of the present disclosure;

FIG. 2 is a view illustrating an electronic device in use according to an embodiment of the present disclosure;

FIG. 3 is an exploded perspective view illustrating an electronic device according to an embodiment of the present disclosure;

FIG. 4 is a cross-sectional view illustrating a deposition apparatus according to an embodiment of the present disclosure;

FIG. 5 is a plan view illustrating a mask assembly according to an embodiment of the present disclosure;

FIG. 6 is an enlarged plan view illustrating an area AA′ of FIG. 5;

FIG. 7A is a cross-sectional view illustrating a mask assembly taken along line I-I′ of FIG. 6;

FIG. 7B is a cross-sectional view illustrating a mask assembly taken along line II-II′ of FIG. 6;

FIG. 7C is a cross-sectional view illustrating a mask assembly taken along line III-III′ of FIG. 6;

FIG. 8A is a view illustrating a portion of a deposition process using a mask assembly according to a comparative example;

FIG. 8B is an enlarged cross-sectional view illustrating an area BB′ of FIG. 8A;

FIG. 8C is a view illustrating a portion of a deposition process using a mask assembly according to an embodiment of the present disclosure;

FIG. 9 is a flowchart illustrating a method of manufacturing a mask assembly according to an embodiment of the present disclosure;

FIGS. 10A to 10J are cross-sectional views of a method of manufacturing a mask assembly according to an embodiment of the present disclosure.

FIG. 11 is a cross-sectional view illustrating a mask assembly according to an embodiment of the present disclosure;

FIG. 12 is a cross-sectional view illustrating a mask assembly according to an embodiment of the present disclosure;

FIG. 13 is a plan view illustrating a display panel manufactured using the mask assembly illustrated in FIG. 5;

FIG. 14 is a cross-sectional view illustrating one pixel shown in FIG. 13; and

FIG. 15 is a view illustrating a deposition process performed by the deposition apparatus shown in FIG. 4.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present.

In the present disclosure, it will be understood that when an element (or area, layer, or portion) is referred to as being “connected to” or “coupled to” another element or layer, it can be directly connected or coupled to the other element or layer or intervening elements or layers may be present.

Like numerals refer to like elements throughout. In the drawings, the thickness, ratio, and dimension of components are exaggerated for effective description of the technical content.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an. ” “Or” means “and/or. ” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

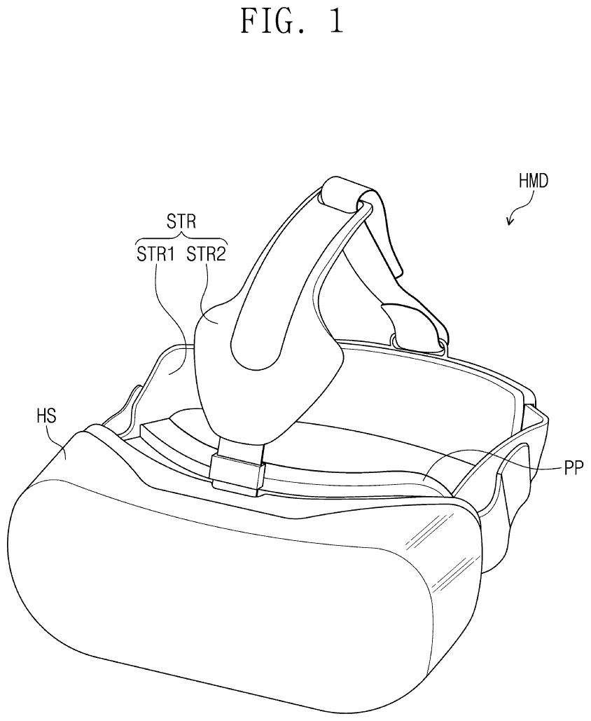

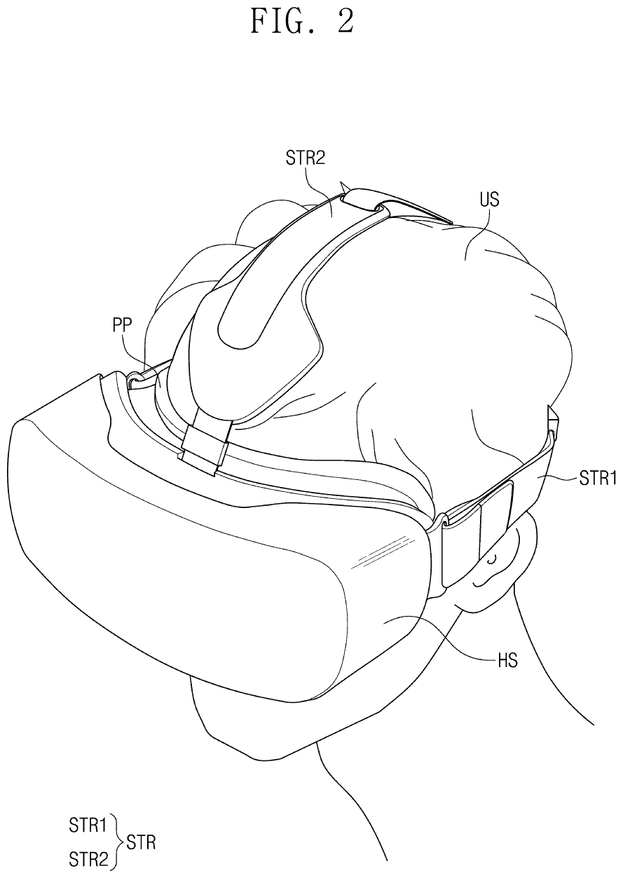

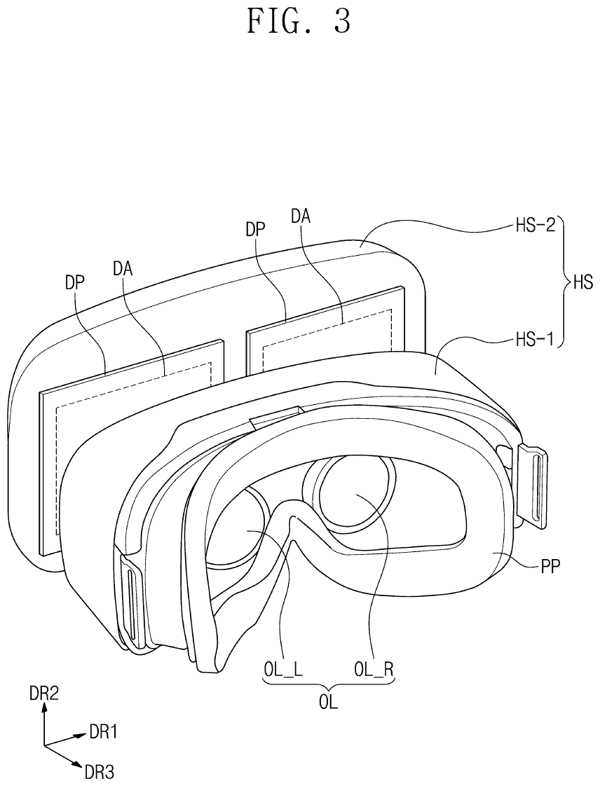

FIG. 1 is a perspective view illustrating an electronic device according to an embodiment of the present disclosure. FIG. 2 is a view illustrating an electronic device in use according to an embodiment of the present disclosure. FIG. 3 is an exploded perspective view illustrating an electronic device according to an embodiment of the present disclosure.

Referring to FIGS. 1 to 3, an embodiment of the electronic device HMD may be activated in response to electrical signals. The electronic device HMD may be a mobile phone, a foldable mobile phone, a notebook computer, a television set, a tablet computer, a car navigation unit, a game unit, or a wearable unit. The wearable unit may be a device that is worn on the body of a user and may include a head-mounted display (HMD) that enables an extended reality (XR) content.

FIG. 1 shows the head-mounted display as an embodiment of the electronic device HMD. In such an embodiment, the electronic device HMD may be a display device that is worn on the head of the user. The electronic device HMD may provide images while blocking a user's view of actual surroundings. The user US wearing the electronic device HMD may find it easier to immerse themselves in virtual reality.

The electronic device HMD may include a body part HS, a strap part STR, a cushion part PP, and a display panel DP. Although not shown in figures, the electronic device HMD may include a variety of sensors and a camera.

The body part HS may be worn on the head of the user US. The body part HS may accommodate the display panel DP displaying the images and an acceleration sensor (not shown). The acceleration sensor may detect the movement of the user US and may transmit a signal to the display panel DP. Accordingly, the display panel DP may provide the images in response to changes in the gaze of the user US. Therefore, the user US may experience a virtual reality that closely resembles real life.

The body part HS may accommodate components with various functions in addition to the above-described components. The body part HS may be referred to as a housing or a case. In an embodiment, a control part (not shown) may be additionally placed on the outside of the body part HS to adjust settings such as volume or screen brightness. The control part may be provided as a physical button or a touch sensor. In addition, the body part HS may accommodate a proximity sensor (not shown) to determine whether the user US wears the electronic device HMD. The body part HS may further include an external display panel.

The body part HS may include a body portion HS-1 and a cover portion HS-2. FIG. 3 illustrates an embodiment having a structure in which the body portion HS-1 is separated from the cover portion HS-2 as a representative example, however, the present disclosure should not be limited thereto or thereby. In another embodiment, for example, the body portion HS-1 may be provided integrally with the cover portion HS-2, as a single unitary indivisible part and the body portion HS-1 and the cover portion HS-2 may not be separated from each other.

The display panels DP may be disposed between the body portion HS-1 and the cover portion HS-2. Each of the display panels DP may display the images through a display area DA. In FIG. 3, an embodiment where a left-eye image and a right-eye image are respectively provided by the display panels DP separated from each other is shown, however, the present disclosure should not be limited thereto or thereby. In another embodiment, for example, the left-eye image and the right-eye image may be displayed through one display panel. The display panels DP may be driven by separate drivers, however, the present disclosure should not be limited thereto or thereby. According to an embodiment, the display panels DP may be driven by a single driver.

The display panels DP may generate the images corresponding to image data input thereto. Each of the display panels DP may be an organic light emitting display panel, an inorganic light emitting display panel, an organic-inorganic light emitting display panel, a quantum dot display panel, a micro-light emitting diode (LED) display panel, a nano-LED display panel, or a liquid crystal display panel. Hereinafter, for convenience of description, embodiments where the display panel DP is the organic light emitting display panel will be mainly described, but the present disclosure should not be limited to the organic light emitting display panel.

The strap part STR may be coupled with the body part HS to allow the body part HS to be easily worn on the user US. The strap part STR may include a main strap STR1 and an upper strap STR2.

The main strap STR1 may be worn around the circumference of the head of the user US. The main strap STR1 may fix the body part HS to the user US so that the body part HS may be tightly fit to the head of the user US. The upper strap STR2 may connect the body part HS to the main strap STR1 along an upper portion of the head of the user US. The upper strap STR2 may effectively prevent the body part HS from slipping down. In addition, the upper strap STR2 may enhance the wearing comfort of the user US by distributing a load of the body part HS.

FIG. 1 illustrates an embodiment having a structure in which a length of the main strap STR1 and a length of the upper strap STR2 are adjustable as a representative example, however, the present disclosure should not be limited thereto or thereby. In another embodiment, for example, the main strap STR1 and the upper strap STR2 may have elasticity, and length-adjustable portions of the main strap STR1 and the upper strap STR2 may be omitted.

The strap part STR may be modified into various shapes other than the shape disclosed in FIGS. 1 and 2 as long as the strap part STR allows the body part HS to be secured to the user US. In an embodiment, the upper strap STR2 may be omitted. In addition, according to an embodiment, the strap part STR may be modified into various shapes, such as a helmet coupled to the body part HS or glasses legs coupled to the body part HS.

The cushion part PP may be disposed between the body part HS and the head of the user US. The cushion part PP may be formed of a material that is easily deformed into different shapes. In an embodiment, the cushion part PP may include a polymer resin (for example, polyurethane, polycarbonate, polypropylene, and polyethylene) or a sponge molded by foaming rubber latex, a urethane-based material, or an acrylic-based material, however, the present disclosure should not be limited thereto or thereby.

The cushion part PP may allow the body part HS to fit securely to the user US, and thus, the wearing comfort of the user US may be enhanced. The cushion part PP may be detachable from the body part HS. According to an embodiment, the cushion part PP may be omitted.

An optical system OL may be disposed in the body portion HS-1 of the body part HS. The optical system OL may enlarge the images provided from the display panels DP. Each of the display panels DP may display the images through the display area DA parallel to a first direction DR1 and a second direction DR2 intersecting the first direction DR1 in a third direction DR3. The optical system OL may be spaced apart from the display panels DP in the third direction DR3. The optical system OL may be placed between the display panels DP and the eyes of the user US. The optical system OL may include a right-eye optical system OL_R and a left-eye optical system OL_L. The left-eye optical system OL_L may provide an enlarged image to a left pupil of the user US, and the right-eye optical system OL_R may provide an enlarged image to a right pupil of the user US.

The left-eye optical system OL_L and the right-eye optical system OL_R may be spaced apart from each other in the first direction DR1. A distance between the right-eye optical system OL_R and the left-eye optical system OL_L may be adjusted to correspond to a distance between two eyes of the user US. In addition, a distance between the optical system OL and the display panels DP may be adjusted depending on the eyesight of the user US.

The optical system OL may be a convex aspherical lens. In an embodiment, for example, the optical system OL may be a pancake lens, but it should not be limited thereto or thereby. In such an embodiment, each of the left-eye optical system OL_L and the right-eye optical system OL_R includes one lens, however, the present disclosure should not be limited thereto or thereby. In another embodiment, each of the left-eye optical system OL_L and the right-eye optical system OL_R may include a plurality of lenses.

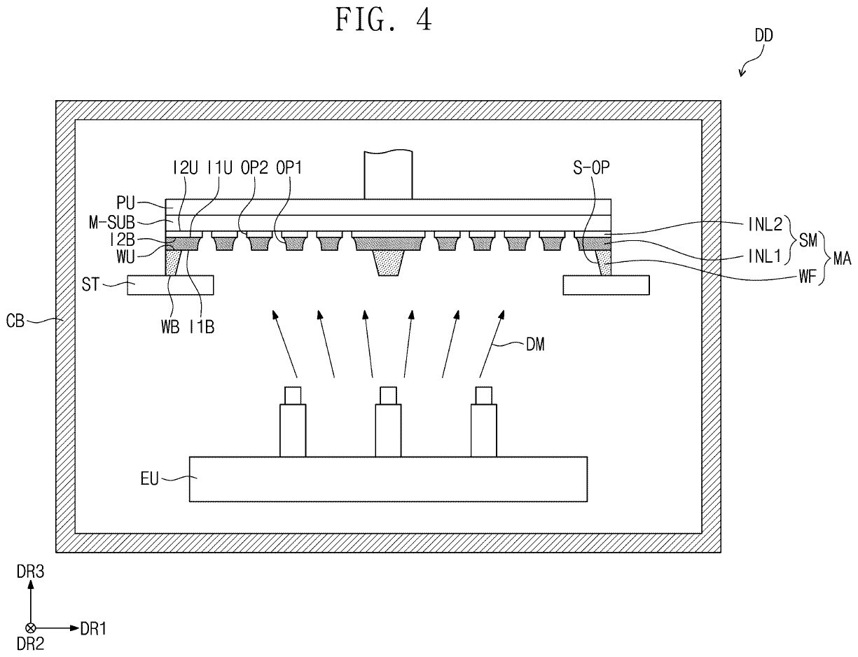

In such an embodiment, since the display panels DP are located very close to the eyes of the user US, the display panels DP may be desired to have high resolution compared to a conventional display panel. According to an embodiment of a method of manufacturing a mask assembly of the present disclosure, the mask assembly MA (refer to FIG. 4) with a structure that maintains deposition reliability even during a manufacturing process of the high-resolution display panel may be provided. Hereinafter, structural characteristics of the mask assembly MA (refer to FIG. 4) and each process of the mask assembly manufacturing method will be described in detail.

FIG. 4 is a cross-sectional view illustrating a deposition apparatus according to an embodiment of the present disclosure.

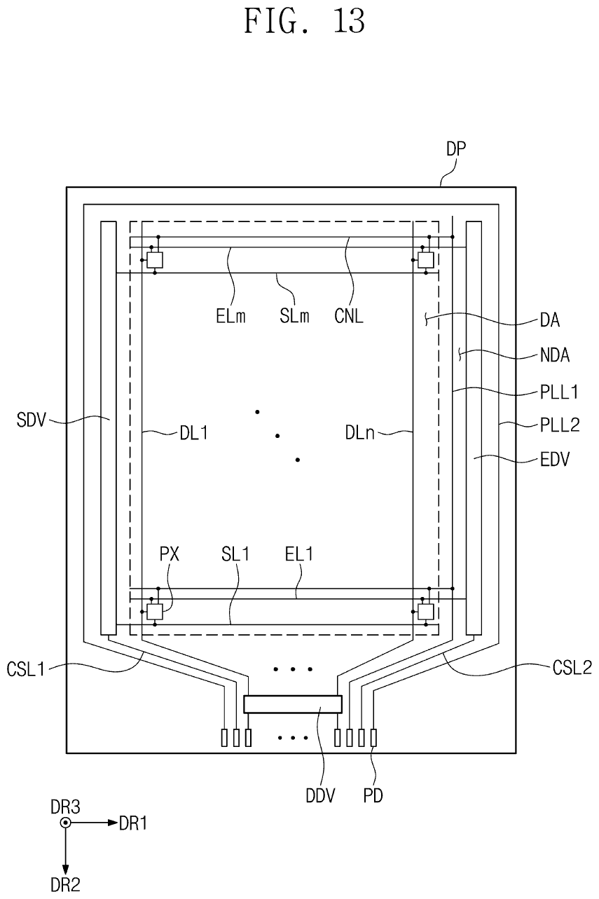

The deposition apparatus DD according to an embodiment of the present disclosure may be used to form one or more of functional layers included in the display panel DP (refer to FIG. 13) described later. In an embodiment, for example, the deposition apparatus DD may be used to perform a deposition process for a deposition pattern EML (refer to FIG. 15) of the display panel DP (refer to FIG. 15).

Referring to FIG. 4, an embodiment of the deposition apparatus DD may include a chamber CB, a fixing unit PU, a deposition unit EU, the mask assembly MA, and a stage ST. The deposition apparatus DD may further include additional mechanical apparatuses to implement an inline system.

The chamber CB may include a bottom surface, a ceiling surface, and sidewalls connecting (or connected between) the bottom surface and the ceiling surface to provide an inner space in the chamber CB. The bottom surface of the chamber CB may be substantially parallel to a plane defined by the first direction DR1 and the second direction DR2, and a normal line direction of the bottom surface of the chamber CB may be substantially parallel to the third direction DR3. In the present disclosure, the expression “when viewed in the plane” or “when viewed in a plan view” may be defined based on a surface parallel to the plane defined by the first direction DR1 and the second direction DR2, and may mean when viewed in the third direction DR3 perpendicular to the plane defined by the first direction DR1 and the second direction DR2.

The fixing unit PU, the deposition unit EU, the mask assembly MA, and the stage ST may be placed in the inner space of the chamber CB. In addition, a target substrate M-SUB may be placed in the inner space of the chamber CB.

The chamber CB may provide an enclosed (or sealed) space therein. Accordingly, the chamber CB may set a deposition condition inside the chamber CB to a vacuum state.

Although not shown in figures, the chamber CB may include one or more gates. The chamber CB may be opened or closed by the gate. The mask assembly MA and the target substrate M-SUB may enter and exit through the gate provided in the chamber CB.

The fixing unit PU may be placed above the deposition unit EU in the chamber CB. The fixing unit PU may function to attach the mask assembly MA to the target substrate M-SUB. FIG. 4 illustrates an embodiment having a structure in which the mask assembly MA is in contact with the target substrate M-SUB as a representative example. However, the present disclosure should not be limited thereto or thereby, and the mask assembly MA may be spaced apart from the target substrate M-SUB with a gap without being in contact with the target substrate M-SUB.

The fixing unit PU may include a magnetic material to secure the mask assembly MA to the target substrate M-SUB. According to an embodiment, the fixing unit PU may include an electro-static chuck. The fixing unit PU may apply an attractive force to the mask assembly MA to effectively prevent the mask assembly MA from sagging due to gravity.

Although not shown in figures, the fixing unit PU may further include a holding part to hold the target substrate M-SUB. The holding part may function to keep the target substrate M-SUB stationary (i.e., to maintain the target substrate M-SUB in a fixed position) during the deposition process. In an embodiment, for example, the holding part may be defined as a groove to which the target substrate M-SUB is detachably coupled.

The target substrate M-SUB may be a processing target on which a deposition material DM is deposited. In an embodiment, for example, the target substrate M-SUB may include a support substrate and a synthetic resin layer disposed on the support substrate and corresponding to a base layer BL (refer to FIG. 15). The support substrate may be removed in the latter stages of the manufacturing process of the display panel DP (refer to FIG. 13). Depending on the component formed through the deposition process, the target substrate M-SUB may include some components of the display panel DP (refer to FIG. 13) formed on the base layer BL (refer to FIG. 15).

The deposition unit EU may be placed in the chamber CB to face the fixing unit PU. The deposition unit EU may include a space that contains the deposition material DM and one or more nozzles that spray the deposition material DM. FIG. 4 illustrates an embodiment where the deposition unit EU includes three nozzles as a representative example, however, the present disclosure should not be limited thereto or thereby.

The deposition material DM may include an inorganic material, a metal material, or an organic material that is able to sublimate or vaporize. The deposition material DM may be deposited on the target substrate M-SUB in a pattern through the mask assembly MA.

The mask assembly MA may be disposed on the stage ST. The mask assembly MA may be disposed between the deposition unit EU and the target substrate M-SUB. In an embodiment, for example, the mask assembly MA may be fixed to the stage ST and may be attached to and detached from the stage ST. An upper surface of the mask assembly MA may face the target substrate M-SUB.

The mask assembly MA may allow the deposition material DM to be deposited on the target substrate M-SUB in the pattern. The mask assembly MA may allow the deposition material DM to selectively pass through specific areas thereof.

The mask assembly MA may include a wafer WF, a first inorganic layer INL1, and a second inorganic layer INL2.

The wafer WF may include silicon (Si).

A cell opening S-OP may be defined through an upper surface WU and a rear surface WB of the wafer WF. The cell opening S-OP may be provided in plural. FIG. 4 illustrates an embodiment where two cell openings S-OP are defined in the mask assembly MA as a representative example.

Each of the cell openings S-OP completely penetrates (or is completely defined or formed) through the wafer WF in a thickness direction of the mask assembly MA.

The first inorganic layer INL1 may be disposed on the wafer WF. In an embodiment, for example, the first inorganic layer INL1 may be disposed on the upper surface WU of the wafer WF. The first inorganic layer INL1 may be directly in contact with the upper surface WU of the wafer WF.

The first inorganic layer INL1 may include a material suitable for isotropic etching. The first inorganic layer INL1 may include a material suitable for wet-etching. In an embodiment, for example, the first inorganic layer INL1 may include silicon oxide (SiOₓ) or aluminum oxide (AlOₓ).

The first inorganic layer INL1 may have a single-layer structure.

The first inorganic layer INL1 may be formed through a chemical vapor deposition (CVD) process. This will be described later.

First openings OP1 may be defined through the first inorganic layer INL1 in the thickness direction. The first openings OP1 may be defined through an upper surface I1U and a rear surface I1B of the first inorganic layer INL1. When viewed in the plane (or when viewed in a plan view or in the third direction DR3), the first openings OP1 may overlap the cell opening S-OP. FIG. 4 illustrates an embodiment having a structure in which five first openings OP1 overlap each cell opening S-OP as a representative example.

The second inorganic layer INL2 may be disposed on the first inorganic layer INL1. In an embodiment, for example, the second inorganic layer INL2 may be disposed on the upper surface I1U of the first inorganic layer INL1. The second inorganic layer INL2 may be directly in contact with the upper surface I1U of the first inorganic layer INL1.

The second inorganic layer INL2 may be formed on the upper surface I1U of the first inorganic layer INL1.

The second inorganic layer INL2 may include a material suitable for anisotropic etching. The second inorganic layer INL2 may include a material suitable for dry-etching. In an embodiment, for example, the second inorganic layer INL2 may include silicon nitride (SiNₓ). The second inorganic layer INL2 may be formed through a chemical vapor deposition (CVD). This will be described later.

The second inorganic layer INL2 may have a multi-layer structure.

Second openings OP2 may be defined through the second inorganic layer INL2 in the thickness direction. When viewed in the plane or in a plan view, the second openings OP2 may overlap the first openings OP1. The second openings OP2 may overlap the cell opening S-OP. FIG. 4 illustrates an embodiment having a structure in which five second openings OP2 overlap each cell opening S-OP as a representative example.

The deposition material DM may pass through the cell opening S-OP, the first opening OP1, and the second opening OP2 and may be blocked in other areas. That is, the deposition material DM may selectively pass through the mask assembly MA and may be deposited on the target substrate M-SUB as a pattern.

When viewed in the plane, the first openings OP1 may overlap the cell opening S-OP. The cell openings S-OP may define an area where a deposition pattern is formed on the target substrate M-SUB.

The deposition material DM may be formed on a deposition surface of the target substrate M-SUB as the pattern corresponding to the first opening OP1 after passing through the cell opening S-OP, the first opening OP1, and the second opening OP2. This will be described later.

The stage ST may be disposed between the deposition unit EU and the fixing unit PU. The stage ST may be placed outside a movement path of the deposition material DM supplied from the deposition unit EU toward the target substrate M-SUB.

The stage ST may support the mask assembly MA. The stage ST may provide a seating surface on which the mask assembly MA is disposed. The seating surface may be substantially parallel to the first direction DR1 and the second direction DR2. The seating surface of the stage ST may be substantially parallel to the bottom of the chamber CB.

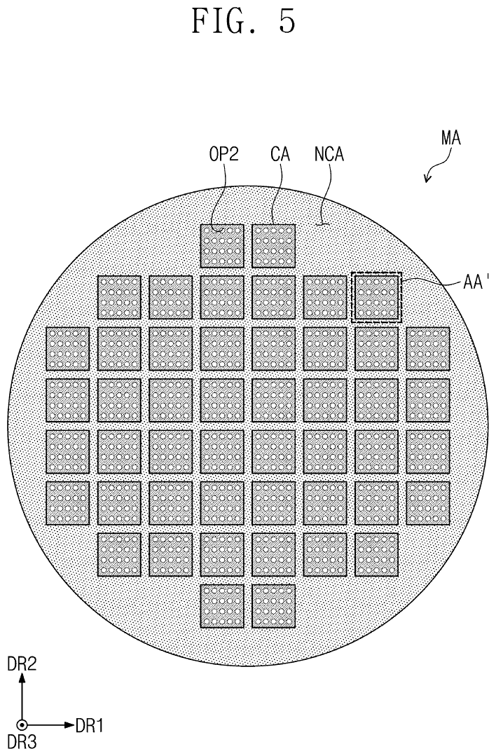

FIG. 5 is a plan view illustrating the mask assembly according to an embodiment of the present disclosure.

Referring to FIG. 5, an embodiment of the mask assembly MA may have a circular shape when viewed in the plane or in a plan view, however, the present disclosure should not be limited thereto or thereby. In an embodiment, for example, the mask assembly MA may have a polygonal shape.

The mask assembly MA may include cell areas CA and a peripheral area NCA surrounding the cell areas CA when viewed in the plane.

The cell areas CA may correspond to the cell openings S-OP (refer to FIG. 4). FIG. 5 illustrates an embodiment where forty-eight cell areas CA are arranged in the first direction DR1 and the second direction DR2 as a representative example, but the present disclosure should not be limited thereto or thereby. The arrangement and number of the cell areas CA may be different or variously modified from those illustrated in FIG. 5.

When viewed in the plane, the second openings OP2 may be defined in the cell areas CA. The second openings OP2 may be arranged in each of the cell areas CA and may be spaced apart from each other in each of the cell areas CA. In an embodiment, for example, the second openings OP2 are arranged in the first direction DR1 and the second direction DR2 in each cell area CA. However, the present disclosure should not be limited thereto or thereby. The second openings OP2 may be defined to correspond to the deposition pattern EML (refer to FIG. 15) formed in the target substrate M-SUB.

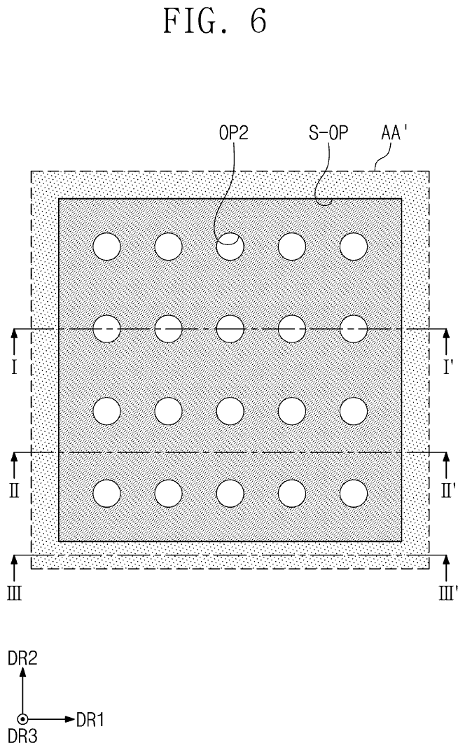

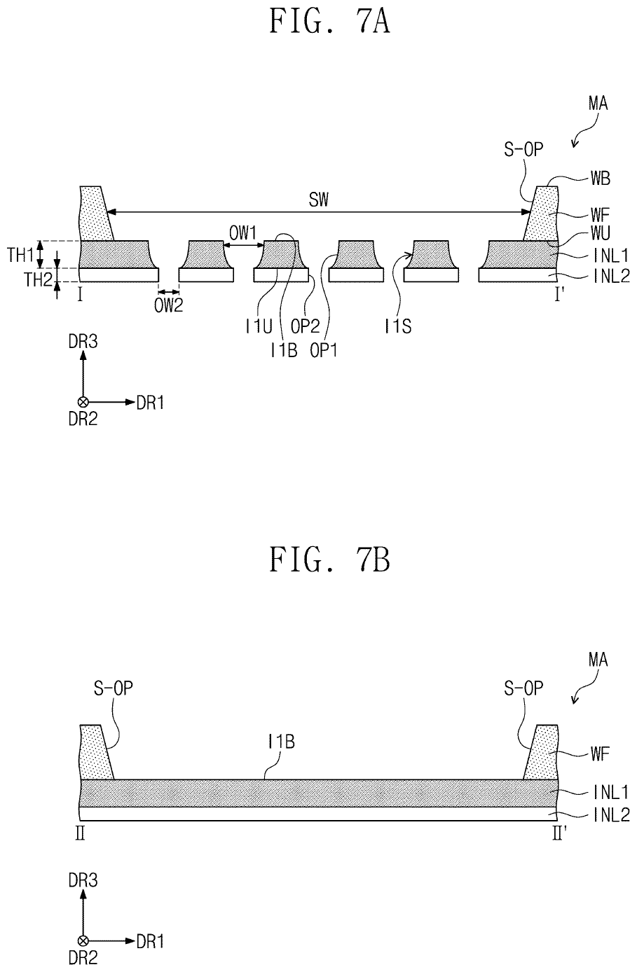

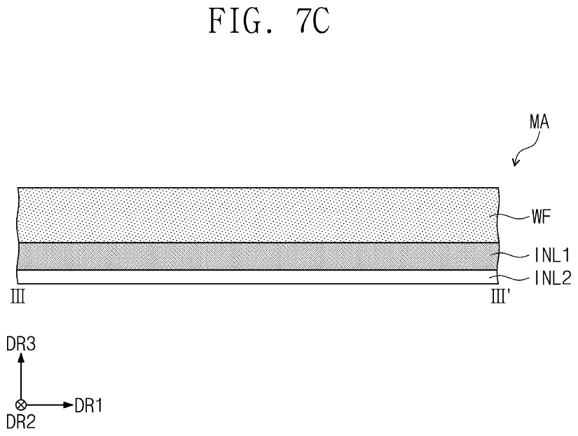

FIG. 6 is an enlarged plan view illustrating an area AA′ of FIG. 5. FIGS. 7A to 7C are cross-sectional views illustrating the mask assembly of FIG. 6.

Hereinafter, structural characteristics of the mask assembly MA will be described with reference to FIGS. 6 and 7A to 7C.

FIG. 6 illustrates an embodiment of the second openings OP2 each having a circular shape when viewed in the plane. However, the shape of the second openings OP2 when viewed in the plane should not be limited to the circular shape. In another embodiment, for example, each of the second openings OP2 may have a polygonal shape when viewed in the plane.

FIG. 6 illustrates an embodiment having a structure in which twenty second openings OP2 are arranged in the first direction DR1 and the second direction DR2, however, this is merely an example, and the present disclosure should not be limited thereto or thereby.

For the convenience of illustration and description, FIGS. 7A to 7C illustrate an embodiment having a structure in which the second inorganic layer INL2 is disposed at a lowermost position and the first inorganic layer INL1 and the wafer WF are stacked in the third direction. That is, the mask assembly illustrated in FIGS. 7A to 7C may be flipped upside down relative to the mask assembly described in FIG. 4. However, for the convenience of explanation, in the following descriptions, the terms ‘upper surface’ and ‘rear surface’ of the components in the mask assembly MA are defined based on the mask assembly MA illustrated in FIG. 4.

FIG. 7A is a cross-sectional view illustrating the mask assembly taken along line I-I′ of FIG. 6.

Referring to FIG. 7A, in an embodiment of the mask assembly MA, a width SW of each of the cell openings S-OP may decrease in a direction from the rear surface WB of the wafer WF to the upper surface WU of the wafer WF. In an embodiment, for example, the width SW of each of the cell openings S-OP may gradually decrease in the direction from the rear surface WB of the wafer WF to the upper surface WU of the wafer WF.

The first openings OP1 may have a width OW1 that decreases in a direction from the rear surface I1B to the upper surface I1U of the first inorganic layer INL1. In an embodiment, for example, the width OW1 of the first openings OP1 may gradually decrease in the direction from the rear surface I1B to the upper surface I1U. FIG. 7A illustrates an embodiment having a structure in which a side surface I1S of the first inorganic layer INL1, which defines each of the first openings OP1, is a curved surface as a representative example. However, the present disclosure should not be limited thereto or thereby.

When viewed in the plane, the first openings OP1 may overlap the second openings OP2.

The second openings OP2 may have a constant width OW2. The width OW2 of the second openings OP2 may be constant in the third direction DR3. However, the present disclosure should not be limited thereto or thereby, and this will be described later.

The first inorganic layer INL1 may have a thickness TH1 greater than a thickness TH2 of the second inorganic layer INL2. In an embodiment, for example, the thickness TH1 of the first inorganic layer INL1 may be greater than or equal to about 100 nm and less than or equal to about 2 micrometers (μm). In an embodiment, for example, the thickness TH2 of the second inorganic layer INL2 may be greater than or equal to about 5 nanometers (nm) and less than or equal to about 50 nm.

FIG. 7B is a cross-sectional view illustrating the mask assembly taken along line II-II′ of FIG. 6.

Referring to FIG. 7B, in an embodiment of the mask assembly MA, the cell opening S-OP may be defined, and the first openings OP1 and the second openings OP2 may not be defined.

The rear surface I1B of the first inorganic layer INL1 may be exposed through the cell opening S-OP.

The second inorganic layer INL2 may be covered by the first inorganic layer INL1 and thus may not be exposed.

FIG. 7C is a cross-sectional view illustrating the mask assembly taken along line III-III′ of FIG. 6.

Referring to FIG. 7C, in an embodiment of the mask assembly MA, the cell openings S-OP (refer to FIG. 7A), the first openings OP1 (refer to FIG. 7A), and the second openings OP2 (refer to FIG. 7B) may not be defined.

Accordingly, the first inorganic layer INL1 may be covered by the wafer WF.

The second inorganic layer INL2 may be covered by the first inorganic layer INL1 and the wafer WF.

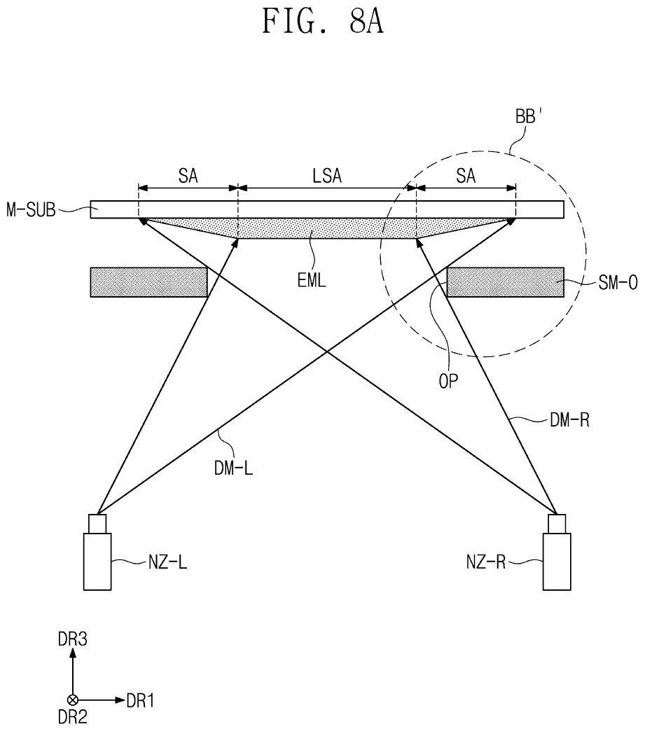

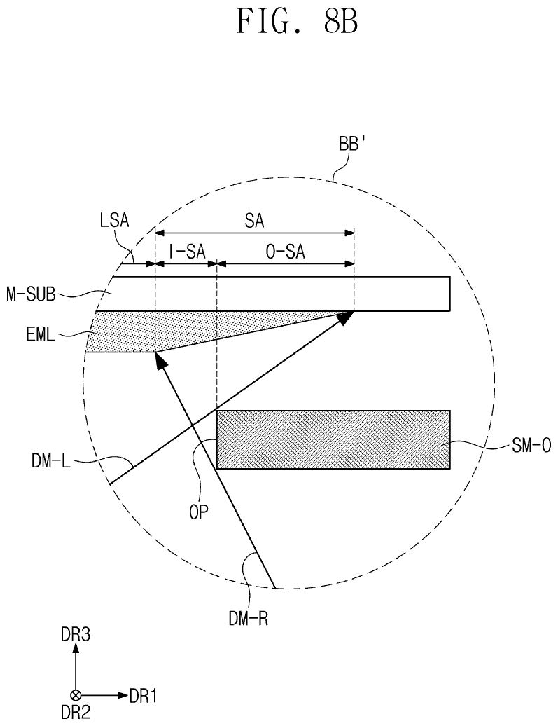

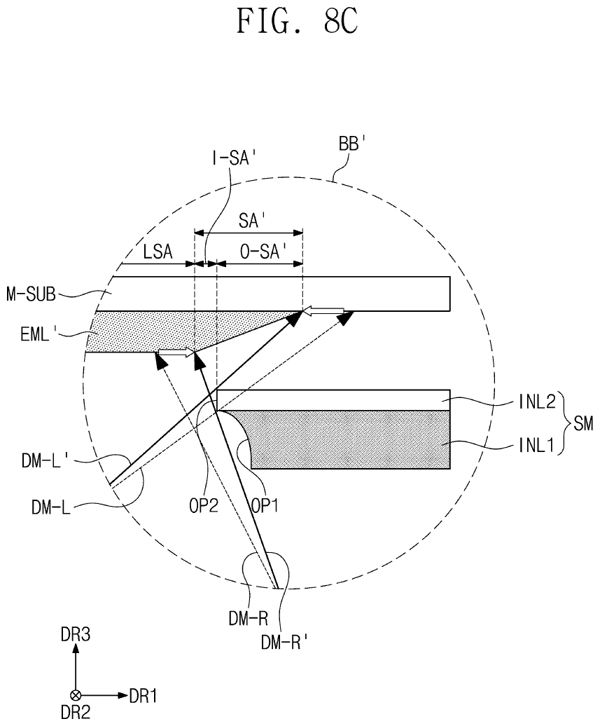

FIG. 8A is a view illustrating a portion of a deposition process using a mask assembly according to a comparative example. FIG. 8B is an enlarged cross-sectional view illustrating an area BB′ of FIG. 8A. FIG. 8C is a view illustrating a portion of a deposition process using a mask assembly according to an embodiment of the present disclosure.

Hereinafter, the mask assembly according to an embodiment of the present disclosure will be described in greater detail with reference to FIGS. 8A to 8C.

FIG. 8A illustrates a process of forming a deposition pattern EML on a target substrate M-SUB using a mask assembly according to the comparative example. For convenience of illustration and description, FIG. 8A illustrates a case having a structure in which a first nozzle NZ-L and a second nozzle NZ-R are spaced apart from each other in the first direction DR1, and other components of a deposition apparatus (refer to DD of FIG. 4) are omitted.

Referring to FIG. 8A, a deposition material (refer to DM of FIG. 4) discharged from the first nozzle NZ-L or the second nozzle NZ-R may be provided into an opening OP defined through a shadow mask SM-O.

However, since a portion of the deposition material DM (refer to FIG. 4) may not be provided parallel to the third direction DR3, a shadow area SA (refer to FIG. 8B) may occur in the deposition pattern EML depending on an angle at which the deposition material DM (refer to FIG. 4) is provided. In the present disclosure, the shadow area SA (refer to FIG. 8B) may refer to an area where the deposition pattern EML is not deposited to a normal thickness.

Referring to FIG. 8B, a side surface of the shadow mask SM-O, which defines the opening OP in the mask assembly according to the comparative example, may be parallel to the third direction DR3 when viewed in a cross-section. Accordingly, the shadow area SA may occur in the deposition process using the shadow mask SM-O.

In the following descriptions, for convenience of description, a path of the deposition material DM (refer to FIG. 4) discharged from the first nozzle NZ-L, which defines one end of the shadow area SA, may be referred to as a first path DM-L, and a path of the deposition material DM (refer to FIG. 4) discharged from the second nozzle NZ-R, which defines the other end of the shadow area SA, may be referred to as a second path DM-R.

The shadow area SA may correspond to an area between a point where the first path DM-L ends and a point where the second path DM-R ends.

The shadow area SA may be divided into an inner shadow area I-SA and an outer shadow area O-SA with respect to an imaginary line extending from the side surface of the shadow mask SM-O, which defines the opening OP.

Referring to FIG. 8C, a shadow mask SM according to an embodiment of the present disclosure may include the first inorganic layer INL1 and the second inorganic layer INL2.

Since the first opening OP1 is defined through the first inorganic layer INL1, an area where the deposition material DM (refer to FIG. 4) is blocked by a rear surface of the shadow mask SM may be reduced. Accordingly, a second modified path DM-R′ may be defined in the deposition process using the shadow mask SM according to an embodiment of the present disclosure.

In such an embodiment, since the shadow mask SM further includes the second inorganic layer INL2 compared to the shadow mask SM-O described with reference to FIG. 8B, the area where the deposition material DM (refer to FIG. 4) blocked by the shadow mask SM may increase. Accordingly, a first modified path DM-L′ may be defined in the deposition process using the shadow mask SM according to an embodiment of the present disclosure.

In the shadow mask SM according to an embodiment of the present disclosure, a shadow area SA′ may be defined by the first modified path DM-L′ and the second modified path DM-R′.

For convenience of illustration and description, in FIG. 8C, the first path DM-L and the second path DM-R described with reference to FIG. 8B are depicted as dotted arrows crossing each other.

According to an embodiment, based on the first modified path DM-L′ and the second modified path DM-R′, an inner shadow area I-SA′ may decrease compared to the inner shadow area I-SA (refer to FIG. 8B) of the comparative example, and an outer shadow area O-SA′ may decrease compared to the outer shadow area O-SA (refer to FIG. 8B) of the comparative example.

Accordingly, the shadow area SA′ may be reduced compared to the shadow area SA (refer to FIG. 8B) described with reference to FIG. 8B.

That is, the mask assembly MA (refer to FIG. 4) according to an embodiment of the present disclosure may effectively prevent or substantially reduce the occurrence of the shadow area SA′. In addition, a normal deposition area LSA may increase.

That is, since the mask assembly MA (refer to FIG. 4) according to an embodiment of the present disclosure includes the first inorganic layer INL1 and the second inorganic layer INL2, a yield and a reliability of the deposition process may be improved. Therefore, the resolution, brightness, and lifespan of the display device manufactured through the deposition process may be improved.

Since the mask assembly MA (refer to FIG. 4) according to an embodiment of the present disclosure includes both the first inorganic layer INL1 and the second inorganic layer INL2 disposed on the wafer WF, a bending strength may be improved due to the inorganic layers. Accordingly, a warpage phenomenon of the mask assembly MA (refer to FIG. 4) may be substantially reduced, and the occurrence of the shadow area SA′ may be effectively prevented.

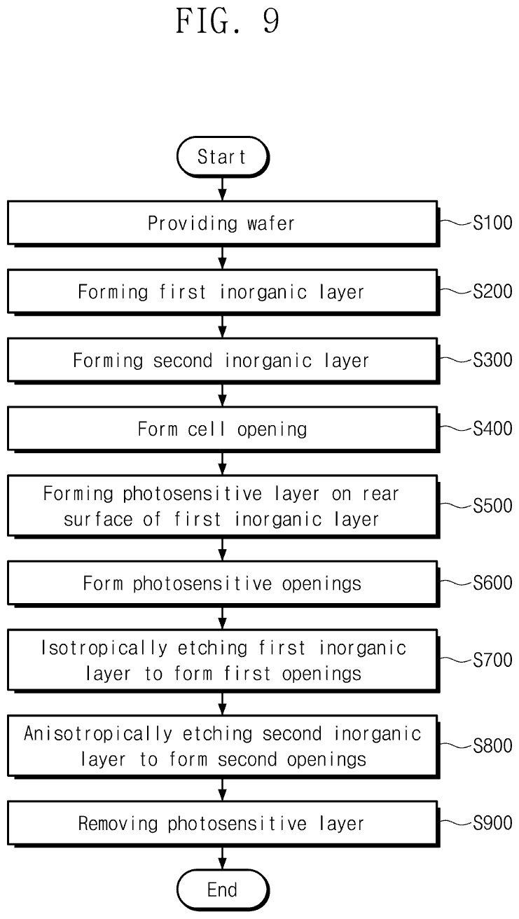

FIG. 9 is a flowchart illustrating the manufacturing method of the mask assembly according to an embodiment of the present disclosure.

Referring to FIG. 9, the manufacturing method of the mask assembly according to an embodiment of the present disclosure includes providing the wafer (S100), forming the first inorganic layer on the wafer (S200), forming the second inorganic layer on the first inorganic layer (S300), etching the wafer to form the cell opening (S400), forming a photosensitive layer on the rear surface of the first inorganic layer exposed through the cell opening (S500), etching the photosensitive layer to form photosensitive openings (S600), isotropically etching the first inorganic layer to form the first openings overlapping the photosensitive openings (S700), and anisotropically etching the second inorganic layer to form the second openings overlapping the first openings (S800).

The manufacturing method of the mask assembly according to an embodiment of the present disclosure may further include removing the photosensitive layer (S900).

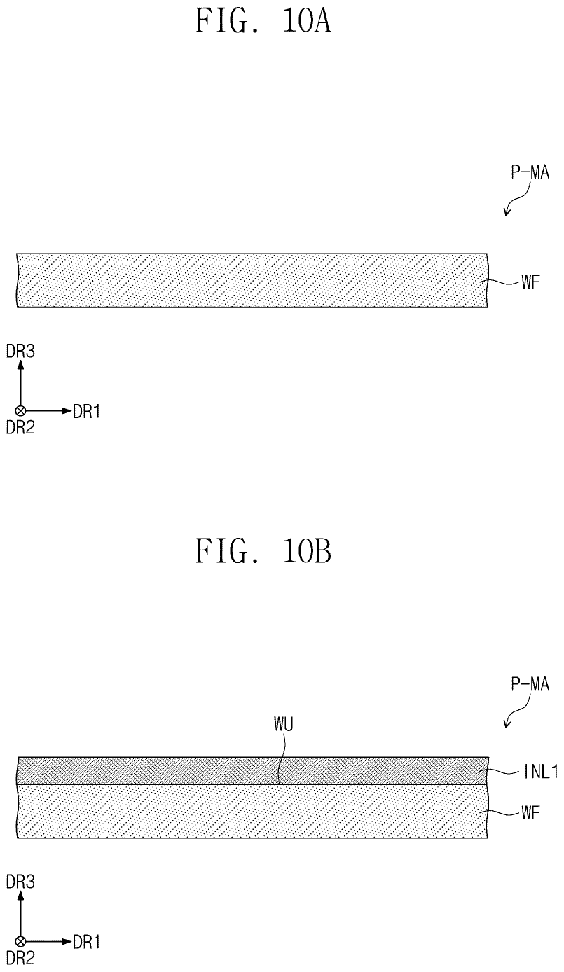

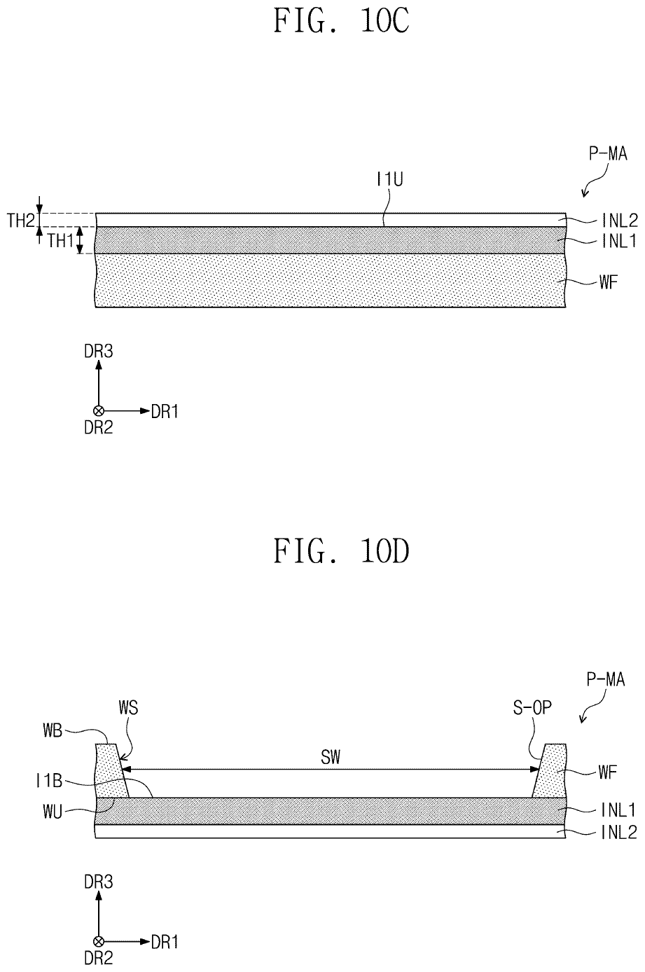

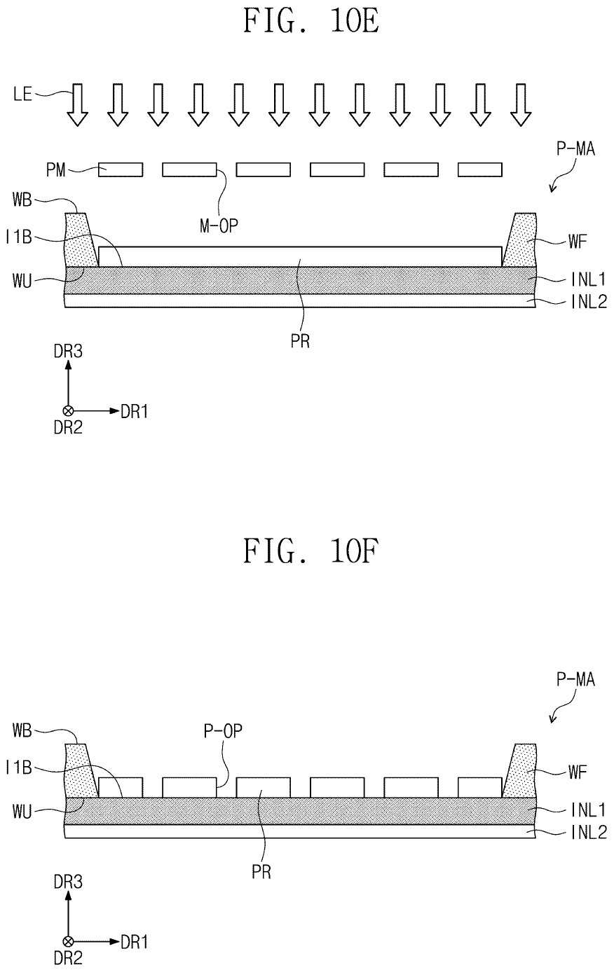

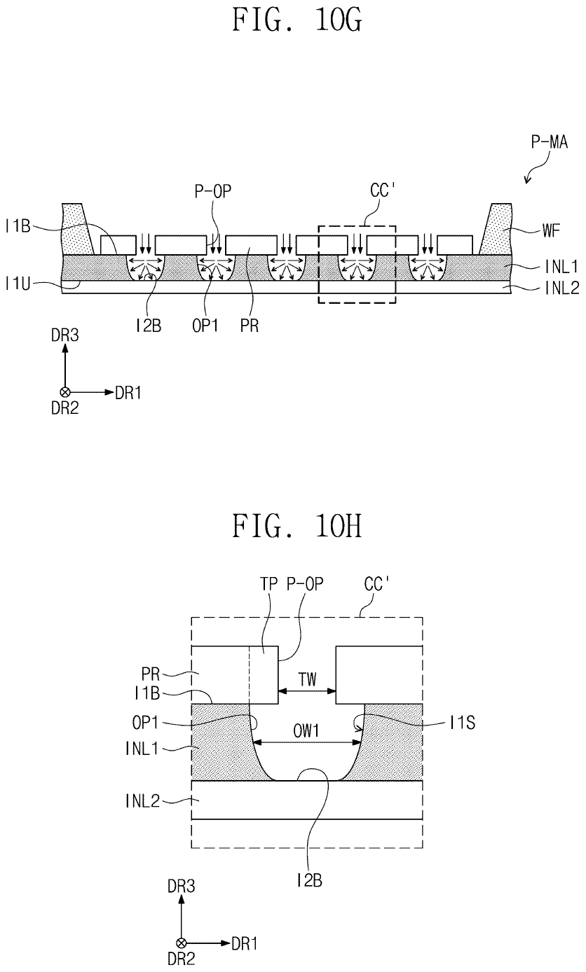

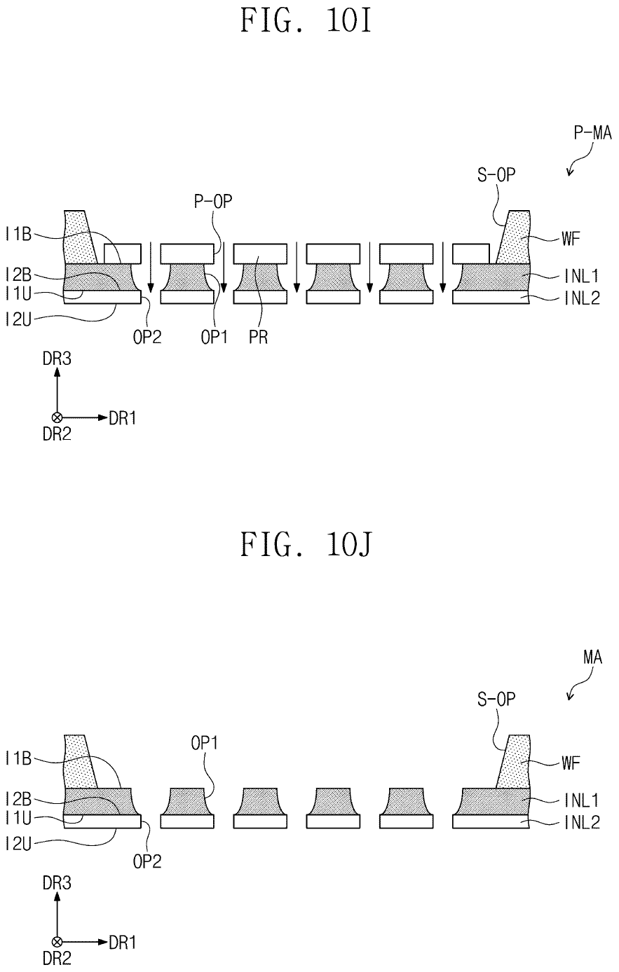

FIGS. 10A to 10J are cross-sectional views of the manufacturing method of the mask assembly according to an embodiment of the present disclosure.

Hereinafter, for convenience of description, the mask assembly MA in a state before completion in the manufacturing process of the mask assembly MA will be referred to as a preliminary mask P-MA.

Referring to FIG. 10A, in an embodiment of the manufacturing method of the mask assembly, the providing of the wafer WF (S100, refer to FIG. 9) may be performed.

Although not shown in figures, the wafer WF according to an embodiment may have a circular shape. The wafer WF may include silicon (Si).

Then, referring to FIG. 10B, in an embodiment of the manufacturing method of the mask assembly, the forming of the first inorganic layer INL1 on the wafer (S200, refer to FIG. 9) may be performed.

The first inorganic layer INL1 may be formed on the upper surface WU of the wafer WF.

The first inorganic layer INL1 may be formed by depositing the deposition material through a chemical vapor deposition (CVD) process.

The deposition material used to form the first inorganic layer INL1 may be the material suitable for isotropic etching.

The deposition material used to form the first inorganic layer INL1 may be the material suitable for wet-etching. In an embodiment, for example, the deposition material used to form the first inorganic layer INL1 may include silicon oxide (SiOₓ) or aluminum oxide (AlOₓ).

Referring to FIG. 10C, in an embodiment of the manufacturing method of the mask assembly, the forming of the second inorganic layer INL2 on the first inorganic layer INL1 (S300, refer to FIG. 9) may be performed.

The second inorganic layer INL2 may be formed on the upper surface I1U of the first inorganic layer INL1.

The second inorganic layer INL2 may be formed by depositing the deposition material through a chemical vapor deposition (CVD) process.

The deposition material used to form the second inorganic layer INL2 may be the material suitable for anisotropic etching.

The deposition material used to form the second inorganic layer INL2 may be the material suitable for dry-etching. The second inorganic layer INL2 may include a different material from the first inorganic layer INL1. In an embodiment, for example, the deposition material used to form the second inorganic layer INL2 may include silicon nitride (SiNₓ).

The thickness TH1 of the first inorganic layer INL1 may be greater than the thickness TH1 of the second inorganic layer INL2. In an embodiment, for example, the thickness TH1 of the first inorganic layer INL1 may be greater than or equal to about 100 nm and less than or equal to about 2 μm. In an embodiment, for example, the thickness TH2 of the second inorganic layer INL2 may be greater than or equal to about 5 nm and less than or equal to about 50 μm.

For convenience of illustration and description, FIGS. 10D to 10J illustrate an embodiment having a structure in which the second inorganic layer INL2 is disposed at a lowermost position and the first inorganic layer INL1 and the wafer WF are stacked in the third direction DR3. That is, the mask assembly illustrated in FIGS. 10D to 10J may be flipped upside down relative to the mask assembly described in FIG. 4. However, for convenience of description, in the following descriptions, the terms ‘upper surface’ and ‘rear surface’ of the components in the mask assembly MA are defined based on the mask assembly MA illustrated in FIG. 4.

Referring to FIG. 10D, in an embodiment of the manufacturing method of the mask assembly, the etching of the wafer WF to form the cell opening S-OP (S400, refer to FIG. 9) may be performed.

The wafer WF may be etched along the direction from the rear surface WB to the upper surface WU. In an embodiment, for example, the wafer WF may be anisotropically etched along the direction from the rear surface WB to the upper surface WU.

The forming of the cell opening S-OP may include wet-etching the wafer WF.

However, in the process of the forming of the cell opening (S400, refer to FIG. 9) is performed through the wet etching process, at least a portion of the wafer WF may be etched in the first and second directions DR1 and DR2 as well as the third direction DR3 by the etching solution.

However, an etch rate of the wafer WF in the third direction DR3 may be greater than an etch rate of the wafer WF in the first and second directions DR1 and DR2. Accordingly, a side surface WS of the wafer WF, which defines the cell opening S-OP, may have a reverse tapered shape when viewed in the cross-section.

Referring to FIGS. 10E and 10F, in an embodiment of the manufacturing method of the mask assembly, the forming of the photosensitive layer PR (S500, refer to FIG. 9) and the forming of the photosensitive openings P-OP (S600, refer to FIG. 9) may be performed.

The photosensitive layer PR may include a photosensitive material. The photosensitive layer PR may be formed by coating the photosensitive material on the rear surface I1B of the first inorganic layer INL1 through a spin coating process or an inkjet process.

FIGS. 10E and 10F illustrate an embodiment where the photosensitive material is a negative photoresist as a representative example. However, the present disclosure should not be limited thereto or thereby, and the photosensitive material may be a positive photoresist.

The forming of the photosensitive openings P-OP (S600, refer to FIG. 9) may be performed by placing a photomask PM through which photo openings M-OP is defined above the preliminary mask P-MA and radiating a light LE to the photosensitive layer PR through the photo openings M-OP of the photomask PM.

Referring to FIGS. 10G and 10H, in an embodiment of the manufacturing method of the mask assembly, the forming of the first openings OP1 (S700, refer to FIG. 9) may be performed. FIG. 10H is an enlarged view of an area CC′ of FIG. 10G.

The forming of the first openings OP1 (S700, refer to FIG. 9) may include isotropically etching the first inorganic layer INL1. In an embodiment, for example, the forming of the first openings OP1 (S700, refer to FIG. 9) may include wet-etching the first inorganic layer INL1 along the direction from the rear surface I1B to the upper surface I1U of the first inorganic layer INL1.

The forming of the first openings (S700, refer to FIG. 9) may include etching the portion of the rear surface I1B of the first inorganic layer, which is exposed through the photosensitive openings P-OP, along the direction from the rear surface I1B of the first inorganic layer to the upper surface I1U of the first inorganic layer.

When viewed in the plane, the first openings OP1 may overlap the photosensitive openings P-OP.

In such an embodiment, since the first openings OP1 are formed by isotropically etching the first inorganic layer INL1, the width OW1 of the first opening OP1 may be greater than a width TW of the photosensitive opening P-OP overlapping the first opening OP1.

Therefore, each of the side surfaces I1S of the first inorganic layer, which defines the first openings OP1, and the photosensitive layer PR may have an under-cut shape when viewed in the cross-section after the forming of the first openings (S700) and before the removing of the photosensitive layer (S900).

That is, a side surface of the photosensitive layer, which defines the photosensitive opening P-OP, may be partially protruded in a direction toward a center of the first opening OP1 when viewed in the plane. In the present disclosure, the protruded portion of the photosensitive layer PR may be referred to as a tip portion TP.

The first openings OP1 may be formed to have the width OW1 that decreases in the direction from the rear surface I1B to the upper surface I1U of the first inorganic layer INL1. In an embodiment, for example, the side surface I1S of the first inorganic layer INL1, which defines each of the first openings OP1, may have a curved shape when viewed in the cross-section, however, the present disclosure should not be limited thereto or thereby.

A portion of the second inorganic layer INL2 may be exposed without being covered by the first inorganic layer INL1. A rear surface I2B of the second inorganic layer INL2 may be exposed through the first opening OP1. Accordingly, the first inorganic layer INL1 may serve as a mask to form the second opening (OP2, refer to FIG. 10I). This will be described later.

Referring to FIG. 10I, in an embodiment of the manufacturing method of the mask assembly, the forming of the second openings OP2 (S800, refer to FIG. 9) may be performed.

The forming of the second openings OP2 (S800, refer to FIG. 9) may include anisotropically etching the second inorganic layer INL2.

The forming of the second openings OP2 (S800) may include etching the portion of the rear surface I2B of the second inorganic layer INL2, which is exposed through the first openings OP1, along the direction from the rear surface I2B of the second inorganic layer INL2 to an upper surface I2U of the second inorganic layer INL2.

In an embodiment, for example, the forming of the second openings OP2 (S800, refer to FIG. 9) may include dry-etching the second inorganic layer INL2 along the direction from the rear surface I2B of the second inorganic layer to the upper surface I2U of the second inorganic layer.

In the forming of the second openings (S800, refer to FIG. 9), the second openings OP2 may be formed using the photosensitive layer PR since the photosensitive layer PR with the photosensitive openings P-OP, which is used in the forming of the first openings OP1 (S700, refer to FIG. 9), is not removed yet.

That is, according to an embodiment of the manufacturing method of the mask assembly (MA, refer to FIG. 4), both the first openings OP1 and the second openings OP2 may be formed using one photosensitive layer PR and the photosensitive openings P-OP defined through the photosensitive layer PR. Accordingly, the time and cost of manufacturing additional masks may be reduced.

Referring to FIG. 10J, in an embodiment of the manufacturing method of the mask assembly, the removing of the photosensitive layer (S900, refer to FIG. 9) may be performed.

The removing of the photosensitive layer (S900, refer to FIG. 9) may include wet-stripping the photosensitive layer PR. However, the present disclosure should not be limited thereto or thereby. In an embodiment, for example, the photosensitive layer (S900, refer to FIG. 9) may be dry-stripped.

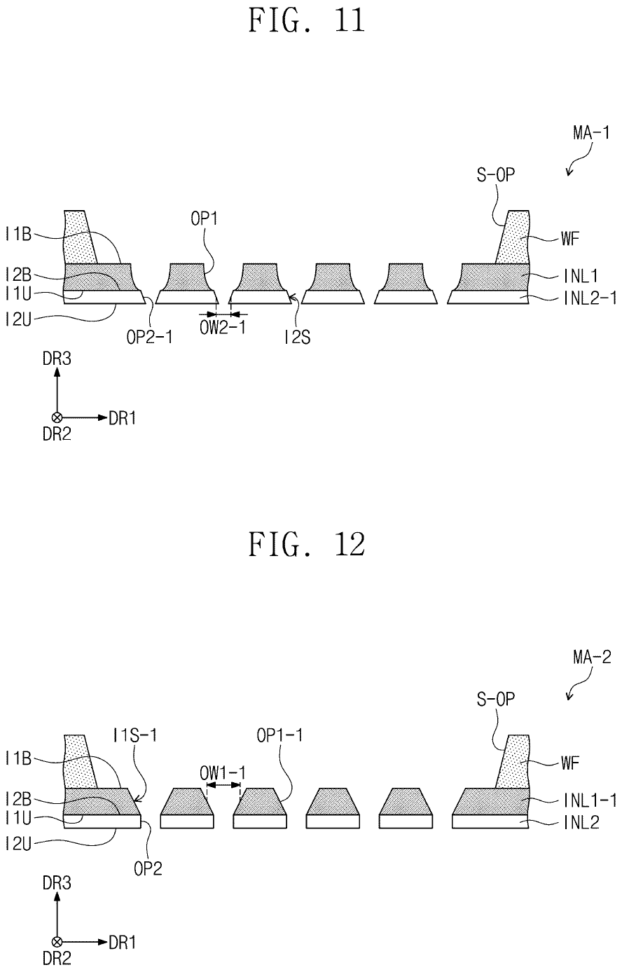

FIG. 11 is a cross-sectional view illustrating a mask assembly according to an embodiment of the present disclosure.

In FIG. 11, the same/similar reference numerals denote the same/similar elements in FIGS. 4 to 810J and thus, any repetitive detailed descriptions of the same/similar elements will be omitted.

Referring to FIG. 11, the mask assembly MA-1 according an embodiment may include a wafer WF, a first inorganic layer INL1, and a second inorganic layer INL2-1.

A second opening OP2-1 may be defined through the second inorganic layer INL2-1. The second opening OP2-1 may have a width OW2-1 that decreases in a direction from a rear surface I2B of the second inorganic layer INL2-1 to an upper surface I2U of the second inorganic layer INL2-1. In an embodiment, for example, the width OW2-1 of the second opening OP2-1 may gradually decrease in the direction from the rear surface I2B of the second inorganic layer INL2-1 to the upper surface I2U of the second inorganic layer INL2-1.

When viewed in the cross-section, a side surface I2S of the second inorganic layer INL2-1, which defines the second opening OP2-1, may be inclined in a direction between the first direction DR1 and the third direction DR3.

FIG. 12 is a cross-sectional view illustrating a mask assembly according to an embodiment of the present disclosure.

In FIG. 12, the same/similar reference numerals denote the same/similar elements in FIGS. 4 to 10J, and thus, any repetitive detailed descriptions of the same/similar elements will be omitted.

Referring to FIG. 12, the mask assembly MA-2 according to an embodiment may include a wafer WF, a first inorganic layer INL1-1, and a second inorganic layer INL2.

A first opening OP1-1 may be defined through the first inorganic layer INL1-1. The first opening OP1-1 may have a width OW1-1 that decreases in a direction from a rear surface I1B of the first inorganic layer INL1-1 to an upper surface I1U of the first inorganic layer INL1-1. In an embodiment, for example, the width OW1-1 of the first opening OP1-1 may gradually decrease in the direction from the rear surface I1B of the first inorganic layer INL1-1 to the upper surface I1U of the first inorganic layer INL1-1.

When viewed in the cross-section, a side surface I1S-1 of the first inorganic layer INL1-1, which defines the first opening OP1-1, may be a plane inclined in a direction between the first direction DR1 and the third direction DR3.

FIG. 12 illustrates an embodiment having the structure in which the side surface I1S-1 of the first inorganic layer INL1-1, which defines the first opening OP1-1, is flat as a representative example, however, the present disclosure should not be limited thereto or thereby. In an embodiment, for example, the side surface I1S-1 of the first inorganic layer INL1-1, which defines the first opening OP1-1, may include a curved surface and a plane surface.

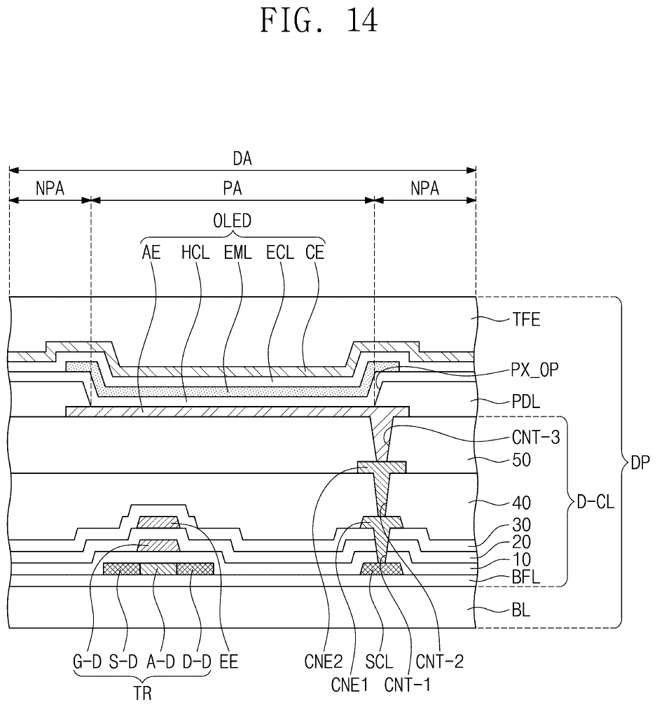

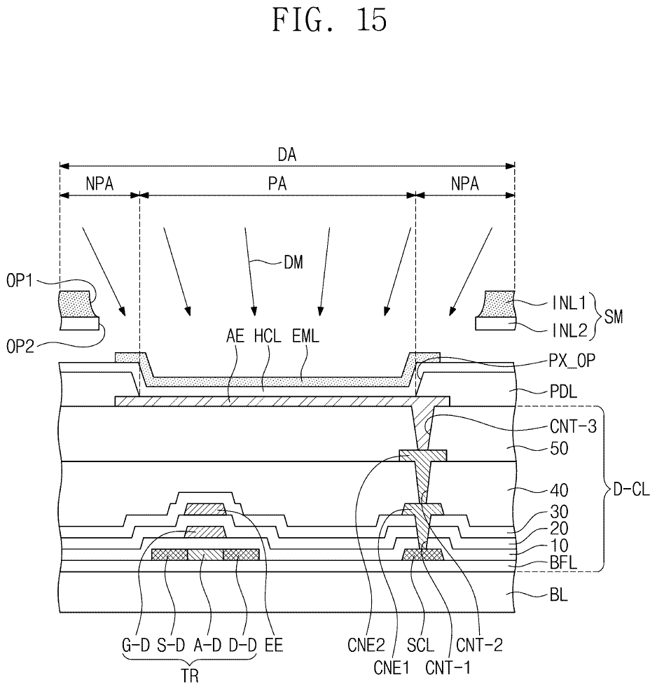

FIG. 13 is a plan view illustrating a display panel manufactured using the mask assembly illustrated in FIG. 5. FIG. 14 is a cross-sectional view illustrating one pixel shown in FIG. 13. FIG. 15 is a view illustrating a deposition process performed by the deposition apparatus shown in FIG. 4.

FIG. 13 is a plan view illustrating the display panel manufactured using the mask assembly illustrated in FIG. 5.

Referring to FIG. 13, an embodiment of the display panel DP may have a rectangular shape defined by short sides extending in the first direction DR1 and long sides extending in the second direction DR2, however, the shape of the display panel DP should not be limited thereto or thereby. The display panel DP may include a display area DA and a non-display area NDA surrounding the display area DA.

The display panel DP may be a light emitting type display panel. The display panel DP may be an organic light emitting display panel or a quantum dot light emitting display panel. A light emitting layer of the organic light emitting display panel may include an organic light emitting material. A light emitting layer of the quantum dot light emitting display panel may include a quantum dot or a quantum rod. Hereinafter, embodiments where the display panel DP is the organic light emitting display panel will be mainly described as a representative example.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, first and second power lines PLL1 and PLL2, connection lines CNL, and a plurality of pads PD. Each of “m” and “n” is a natural number.

The pixels PX may be arranged in the display area DA. A scan driver SDV and an emission driver EDV may be disposed in the non-display area NDA respectively adjacent to the long sides of the display panel DP. A data driver DDV may be disposed in the non-display area NDA adjacent to one short side of the short sides of the display panel DP. When viewed in the plane, the data driver DDV may be disposed adjacent to a lower end of the display panel DP.

The scan lines SL1 to SLm may extend in the first direction DR1 and may be connected to the pixels PX and the scan driver SDV. The data lines DL1 to DLn may extend in the second direction DR2 and may be connected to the pixels PX and the data driver DDV. The emission lines EL1 to ELm may extend in the first direction DR1 and may be connected to the pixels PX and the emission driver EDV.

The first power line PLL1 may extend in the second direction DR2 and may be disposed in the non-display area NDA. The first power line PLL1 may be disposed between the display area DA and the emission driver EDV, however, it should not be limited thereto or thereby. According to an embodiment, the first power line PLL1 may be disposed between the display area DA and the scan driver SDV.

The connection lines CNL may extend in the first direction DR1 and may be arranged in the second direction DR2. The connection lines CNL may be connected to the first power line PLL1 and the pixels PX. A first voltage may be applied to the pixels PX through the first power line PLL1 and the connection lines CNL connected to the first power line PLL1.

The second power line PLL2 may be disposed in the non-display area NDA. The second power line PLL2 may extend along the long sides of the display panel DP and the other short side at which the data driver DDV is not disposed in the display panel DP. The second power line PLL2 may be disposed outside the scan driver SDV and the emission driver EDV.

Although not shown in figures, the second power line PLL2 may extend to the display area DA and may be connected to the pixels PX. A second voltage having a level lower than that of the first voltage may be applied to the pixels PX through the second power line PLL2.

The first control line CSL1 may be connected to the scan driver SDV and may extend toward the lower end of the display panel DP when viewed in the plane. The second control line CSL2 may be connected to the emission driver EDV and may extend toward the lower end of the display panel DP when viewed in the plane. The data driver DDV may be disposed between the first control line CSL1 and the second control line CSL2.

The pads PD may be disposed on the display panel DP. The pads PD may be disposed closer to the lower end of the display panel DP than the data driver DDV is. The data driver DDV, the first power line PLL1, the second power line PLL2, the first control line CSL1, and the second control line CSL2 may be connected to the pads PD. The data lines DL1 to DLn may be connected to the data driver DDV, and the data driver DDV may be connected to the pads PD corresponding to the data lines DL1 to DLn.

Light emitting elements of the display panel DP may be formed by the cell areas CA shown in FIG. 5. Unit areas corresponding to the display panel DP may be defined in the target substrate M-SUB refer to FIG. 4. When the light emitting elements are formed in the unit areas, the unit areas may be cut. As a result, the display panel DP shown in FIG. 13 may be manufactured.

Although not shown in figures, a timing controller to control an operation of the scan driver SDV, the data driver DDV, and the emission driver EDV and a voltage generator to generate the first and second voltages may be disposed on a printed circuit board. The timing controller and the voltage generator may be connected to corresponding pads PD through the printed circuit board.

The scan driver SDV may generate a plurality of scan signals, and the scan signals may be applied to the pixels PX through the scan lines SL1 to SLm. The data driver DDV may generate a plurality of data voltages, and the data voltages may be applied to the pixels PX through the data lines DL1 to DLn. The emission driver EDV may generate a plurality of emission signals, and the emission signals may be applied to the pixels PX through the emission lines EL1 to ELm.

The pixels PX may receive the data voltages in response to the scan signals. The pixels PX may emit a light having a luminance corresponding to the data voltages in response to the emission signals, and thus, an image may be displayed. An emission time of the pixels PX may be controlled by the emission signals.

The lines described above may include the data lines DL1 to DLn. Pads connected to the lines described above may include the pads PD shown in FIG. 13. The display panel DP in which the light emitting layers of the pixels PX are not formed may be defined as the target substrate M-SUB refer to FIG. 4 described above.

FIG. 14 is a cross-sectional view illustrating one pixel shown in FIG. 13.

An embodiment of a pixel PX may be disposed on a base substrate BL and may include a transistor TR and a light emitting element OLED. The transistors TR and the light emitting elements OLED of the pixels PX may be connected to the data lines DL1 to DLn and the first and second power lines PLL1 and PLL2. The transistors TR and the light emitting elements OLED of the pixels PX may be connected to the pads PD through the data lines DL1 to DLn and the first and second power lines PLL1 and PLL2.

The light emitting element OLED may include a first electrode AE, a second electrode CE, a hole control layer HCL, an electron control layer ECL, and a deposition pattern EML. In an embodiment, the deposition pattern EML may be referred to as the light emitting layer EML. The first electrode AE may be an anode electrode, and the second electrode CE may be a cathode electrode.

The transistor TR and the light emitting element OLED may be disposed on the base substrate BL. In an embodiment, for example, one transistor TR is illustrated, however, the pixel PX may include a plurality of transistors and at least one capacitor to drive the light emitting element OLED.

The display area DA may include a light emitting area PA corresponding to the pixel PX and a non-light-emitting area NPA around the light emitting area PA. The light emitting element OLED may be disposed in the light emitting area PA.

The base substrate BL may include a flexible plastic substrate. In an embodiment, for example, the base substrate BL may include transparent polyimide (PI). A buffer layer BFL may be disposed on the base substrate BL, and the buffer layer BFL may be an inorganic layer.

A semiconductor pattern may be disposed on the buffer layer BFL. The semiconductor pattern may include polycrystalline silicon, however, it should not be limited thereto or thereby. According to an embodiment, the semiconductor pattern may include amorphous silicon or metal oxide.

The semiconductor pattern may be doped with an N-type dopant or a P-type dopant. The semiconductor pattern may include a high-doped region and a low-doped region. The high-doped region may have a conductivity greater than that of the low-doped region and may substantially serve as a source electrode and a drain electrode of the transistor TR. The low-doped region may substantially correspond to an active (or a channel) of the transistor.

A source S-D, an active A-D, and a drain D-D of the transistor TR may be formed from the semiconductor pattern. A first insulating layer 10 may be disposed on the semiconductor pattern. A gate G-D of the transistor TR may be disposed on the first insulating layer 10. A second insulating layer 20 may be disposed on the gate G-D. A third insulating layer 30 may be disposed on the second insulating layer 20.

Connection electrodes CNE1, CNE2 may be disposed between the transistor TR and the light emitting element OLED to connect the transistor TR to the light emitting element OLED. The connection electrodes may include a first connection electrode CNE1 and a second connection electrode CNE2.

The first connection electrode CNE1 may be disposed on the third insulating layer 30 and may be connected to the drain D-D via a first contact hole CNT-1 defined through the first, second, and third insulating layers 10, 20, and 30. A fourth insulating layer 40 may be disposed on the first connection electrode CNE1. A fifth insulating layer 50 may be disposed on the fourth insulating layer 40.

The second connection electrode CNE2 may be disposed on the fourth insulating layer 40. The second connection electrode CNE2 may be connected to the first connection electrode CNE1 via a second contact hole CNT-2 defined through the fourth insulating layer 40. A fifth insulating layer 50 may be disposed on the second connection electrode CNE2. Each of the first to fifth insulating layers 10 to 50 may be an inorganic layer or an organic layer.

The first electrode AE may be disposed on the fifth insulating layer 50. The first electrode AE may be connected to the second connection electrode CNE2 via a third contact hole CNT-3 defined through the fifth insulating layer 50. A pixel definition layer PDL may be disposed on the first electrode AE and the fifth insulating layer 50 to expose a portion of the first electrode AE. An opening PX_OP may be defined through the pixel definition layer PDL to expose the portion of the first electrode AE.

The hole control layer HCL may be disposed on the first electrode AE and the pixel definition layer PDL. The hole control layer HCL may be commonly disposed in the light emitting area PA and the non-light-emitting area NPA. The hole control layer HCL may include a hole transport layer and a hole injection layer.

The light emitting layer EML may be disposed on the hole control layer HCL. The light emitting layer EML may be disposed in an area corresponding to the opening PX_OP. The light emitting layer EML may include an organic material and/or an inorganic material. The light emitting layer EML may generate a light having one of red, green, and blue colors.

The electron control layer ECL may be disposed on the light emitting layer EML and the hole control layer HCL. The electron control layer ECL may be commonly disposed in the light emitting area PA and the non-light-emitting area NPA. The electron control layer ECL may include an electron transport layer and an electron injection layer.

The second electrode CE may be disposed on the electron control layer ECL. The second electrode CE may be commonly disposed over the pixels PX.

A thin film encapsulation layer TFE may be disposed on the light emitting element OLED. The thin film encapsulation layer TFE may be disposed on the second electrode CE to cover the pixel PX. The thin film encapsulation layer TFE may include at least two inorganic layers and an organic layer disposed between the inorganic layers. The inorganic layers may protect the pixel PX from moisture and oxygen. The organic layer may protect the pixel PX from a foreign substance such as dust particles.

The first voltage may be applied to the first electrode AE via the transistor TR, and the second voltage having the level lower than the first voltage may be applied to the second electrode CE. Holes and electrons injected into the light emitting layer EML may be recombined to generate excitons, and the light emitting element OLED may emit the light by the excitons that return to a ground state from an excited state.

FIG. 15 is a view illustrating the deposition process performed by the deposition apparatus shown in FIG. 4.

Referring to FIG. 15, the components from the base substrate BL to the hole control layer HCL may correspond to the target substrate M-SUB shown in FIG. 4.

The mask assembly MA (refer to FIG. 4) may be disposed to face the target substrate M-SUB. However, for the sake of explanation, only a portion of the shadow mask SM included in the mask assembly MA (refer to FIG. 4) is shown, and other components are omitted.

The mask assembly MA (refer to FIG. 4) may be disposed closer to the target substrate M-SUB.

The deposition material DM may be provided onto the target substrate M-SUB through the first and second openings OP1 and OP2. The light emitting layer EML may be formed on the target substrate M-SUB by the deposition material DM.

According to embodiments of the manufacturing method of the mask assembly MA (refer to FIG. 4), the mask assembly MA (refer to FIG. 4) capable of reducing the occurrence of the shadow area may be manufactured.

In addition, according to embodiments of the manufacturing method of the mask assembly MA (refer to FIG. 4), the manufacturing process of the mask assembly MA (refer to FIG. 4) may be simplified, and the time and cost for the manufacturing process may be reduced.

When the mask assembly MA (refer to FIG. 4) manufactured through the manufacturing method of the mask assembly MA (refer to FIG. 4) according to an embodiment of the present disclosure is used, the yield and the reliability of the deposition process may be improved. Therefore, the resolution, brightness, and lifespan of the display device DP (refer to FIG. 13) manufactured through the deposition process may be improved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A method of manufacturing a mask assembly, the method comprising:
providing a wafer;
forming a first inorganic layer on the wafer;
forming a second inorganic layer on the first inorganic layer;
etching the wafer to form a cell opening;
forming a photosensitive layer on a rear surface of the first inorganic layer exposed through the cell opening;
etching the photosensitive layer to form photo openings;
isotropically etching the first inorganic layer to form first openings overlapping the photo openings; and
anisotropically etching the second inorganic layer to form second openings overlapping the first openings.

2. The method of claim 1, wherein the forming the first openings comprises wet-etching the first inorganic layer along a direction from the rear surface of the first inorganic layer to an upper surface of the first inorganic layer.

3. The method of claim 1, wherein the forming the second openings comprises dry-etching the second inorganic layer along a direction from a rear surface of the second inorganic layer to an upper surface of the second inorganic layer.

4. The method of claim 1, wherein
the forming the first inorganic layer comprises depositing one of silicon oxide (SiOx) and aluminum oxide (AlOx) on an upper surface of the wafer through a chemical vapor deposition (CVD) process, and
the forming the second inorganic layer comprises depositing silicon nitride (SiNx) on an upper surface of the first inorganic layer through a chemical vapor deposition (CVD) process.

5. The method of claim 1, wherein the forming the first openings comprises etching a portion of the rear surface of the first inorganic layer, which is exposed through the photo openings, in a direction from the rear surface of the first inorganic layer to an upper surface of the first inorganic layer.

6. The method of claim 1, wherein the forming the second openings comprises etching a portion of a rear surface of the second inorganic layer, which is exposed through the first openings, in a direction from the rear surface of the second inorganic layer to an upper surface of the second inorganic layer.

7. The method of claim 1, further comprising removing the photosensitive layer.

8. The method of claim 7, wherein the removing the photosensitive layer comprises wet-stripping the photosensitive layer.

9. The method of claim 7, wherein each of side surfaces the first inorganic layer, which defines the first openings, has an under-cut shape when viewed in a cross-section after the forming the first openings and before the removing the photosensitive layer.

10. The method of claim 1, wherein the forming the cell opening comprises wet-etching the wafer in a direction from a rear surface of the wafer to an upper surface of the wafer, and the cell opening has a width that decreases in a direction from the rear surface of the wafer to the upper surface of the wafer when viewed in a cross-section.

11. The method of claim 1, wherein
the first inorganic layer has a thickness greater than or equal to about 100 nm and less than or equal to about 2 μm, and
the second inorganic layer has a thickness greater than or equal to about 5 nm and less than or equal to about 50 nm.

12. A mask assembly comprising:
a wafer through which cell openings are defined;
a first inorganic layer disposed on the wafer and provided with first openings completely penetrating through upper and rear surfaces of the first inorganic layer; and
a second inorganic layer disposed on the first inorganic layer and provided with second openings defined through the second inorganic layer and overlapping the first openings,
wherein each of the first openings has a width which decreases in a direction from the rear surface of the first inorganic layer to the upper surface of the first inorganic layer.

13. The mask assembly of claim 12, wherein the first inorganic layer has a thickness greater than a thickness of the second inorganic layer.

14. The mask assembly of claim 12, wherein the first inorganic layer has a thickness greater than or equal to about 100 nm and less than or equal to about 2 μm.

15. The mask assembly of claim 12, wherein the second inorganic layer has a thickness greater than or equal to about 5 nm and less than or equal to about 50 nm.

16. The mask assembly of claim 12, wherein each of the cell openings overlaps the first openings and the second openings when viewed in a plan view.

17. The mask assembly of claim 12, wherein
the wafer comprises silicon,
the first inorganic layer comprises one of silicon oxide (SiOx) and aluminum oxide (AlOx), and
the second inorganic layer comprises silicon nitride (SiNx).

18. The mask assembly of claim 12 wherein
each of the cell openings completely penetrates through the wafer in a thickness direction, and
each of the cell openings has a width which decreases in a direction from a rear surface of the wafer to an upper surface of the wafer when viewed in a cross-section.

19. The mask assembly of claim 12 wherein the second openings are spaced apart from each other when viewed in a plan view.

20. The mask assembly of claim 12 wherein
the first inorganic layer has a single-layer structure, and
the second inorganic layer has a multi-layer structure.
